(19) United States
(12) Patent Application Publication
(10) Pub. No.: US 2014/0199810 A1
(43) Pub. Date: Jul. 17, 2014

(54) Methods for Forming Semiconductor Devices Using Sacrificial Layers

(71) Applicant: Samsung Electronics Co., Ltd., Suwon-si (KR)

(72) Inventors: Jin-Ho Park, Yongin-si (KR); Pil-Kyu Kang, Anyang-si (KR); Tae-Yeong Kim, Suwon-si (KR); Byung-Lyul Park, Seoul (KR); Jum-Yong Park, Yongin-si (KR); Kyu-Ha Lee, Yongin-si (KR); Deok-Young Jung, Seoul (KR); Gil-Heyun Choi, Seoul (KR)

(73) Assignee: Samsung Electronics Co., Ltd., Suwon-si (KR)

(21) Appl. No.: 14/153,545

(22) Filed: Jan. 13, 2014

(30) Foreign Application Priority Data
Jan. 14, 2013 (KR) 10-2013-0004028

(51) Int. Cl. H01L 23/00

(52) U.S. Cl. CPC H01L 24/30
USPC 438/107

(57) ABSTRACT

A fabricating method for a semiconductor device is provided. The fabricating method includes providing a first wafer, forming a sacrificial layer on the first wafer, forming a release layer on the sacrificial layer, forming an adhesive layer on the release layer, and placing a second wafer on the adhesive layer and bonding the first wafer to the second wafer.

### CROSS-REFERENCE TO RELATED APPLICATIONS

This application claims priority from Korean Patent Application No. 10-2013-0004028 filed on Jan. 14, 2013 in the Korean Intellectual Property Office, and all the benefits accruing therefrom under 35 U.S.C. 119, the contents of which in its entirety are herein incorporated by reference.

### BACKGROUND

1. Field of the Invention

Embodiments of the present invention relate to fabricating methods for a semiconductor device.

2. Description of the Related Art

Current research involves methods for manufacturing a 3D integrated circuit by forming a TSV (Through Silicon Via). One process for forming TSV is to use a WSS (Wafer Supporting System) process. In the WSS process, in order to grind a back surface of a device wafer, a device wafer can be bonded to a carrier wafer, which can then be debonded from the device wafer.

### SUMMARY

Embodiments of the present invention will be described.

According to some embodiments of the present invention, a fabricating method for a semiconductor device is provided, the fabricating method including providing a first wafer, forming a sacrificial layer on the first wafer, forming a release layer on the sacrificial layer, forming an adhesive layer on the release layer, and placing a second wafer on the adhesive layer and bonding the first wafer to the second wafer.

According to other embodiments of the present invention, a fabricating method for a semiconductor device is provided, the fabricating method including providing a first wafer having one or more through silicon vias formed therein, forming a first sacrificial layer on the first wafer, forming a first release layer on the first sacrificial layer, forming a first adhesive layer on the first release layer, placing a second wafer on the first adhesive layer and bonding the first wafer to the second wafer, and back-grinding the first wafer to expose the one or more through silicon vias.

According to some embodiments, a method for forming a semiconductor device includes providing a first wafer, forming a porous sacrificial layer on the first wafer, forming a release layer on the porous sacrificial layer, forming an adhesive layer on the release layer and placing a second wafer on the adhesive layer and bonding the first wafer to the second wafer. The porous sacrificial layer may have less than 90% porosity.

According to some embodiments, forming the release layer may include forming a metal layer and forming an organic compound layer on the metal layer. Forming the organic compound layer may include forming an organic compound that reacts with ultra violet light to release the second wafer from the first wafer. The method may also include forming a base film interposed between the first and second wafers.

According to further embodiments, the method may include forming a second porous sacrificial layer on the second wafer, forming a second release layer on the second porous sacrificial layer and forming a second adhesive layer on the second release layer. Bonding the first wafer to the second wafer may include placing the second adhesive layer on the first adhesive layer.

### BRIEF DESCRIPTION OF THE DRAWINGS

Embodiments of the present invention will be described with reference to the attached drawings:

FIG. 1 is a schematic flowchart for explaining a fabricating method of a semiconductor device according to some embodiments of the present invention;

FIGS. 2 to 10 schematically illustrate a fabricating method of the semiconductor device according to some embodiments of the present invention;

FIG. 11 is a schematic flowchart for explaining a fabricating method of a semiconductor package using a fabricating method of a semiconductor device according to some embodiments of the present invention;

FIGS. 12 to 14 schematically illustrate a fabricating method of the semiconductor package using a fabricating method of a semiconductor device according to some embodiments of the present invention;

FIGS. 15 to 17 schematically illustrate a fabricating method of a semiconductor device according to some embodiments of the present invention;

FIG. 18 is a schematic flowchart for explaining a fabricating method of a semiconductor device according to some embodiments of the present invention;

FIGS. 19 to 21 schematically illustrate a fabricating method of the semiconductor device according to some embodiments of the present invention; and

FIGS. 22 to 24 schematically illustrate a fabricating method of a semiconductor device according to some embodiments of the present invention.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art. The same reference numbers indicate the same components throughout the specification. In the attached figures, the thickness of layers and regions may be exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may be interpreted as consistent with the entirety of the figures and written description.

The present invention will be described with reference to perspective views, cross-sectional views, and/or plan views, in which preferred embodiments of the invention are shown. Thus, the profile of an exemplary view may be modified according to manufacturing techniques and/or allowances. That is, the embodiments of the invention are not intended to limit the scope of the present invention but cover all changes and modifications that can be caused due to a change in manufacturing process. Thus, regions shown in the drawings are illustrated in schematic form and the shapes of the regions are presented simply by way of illustration and not as a limitation.

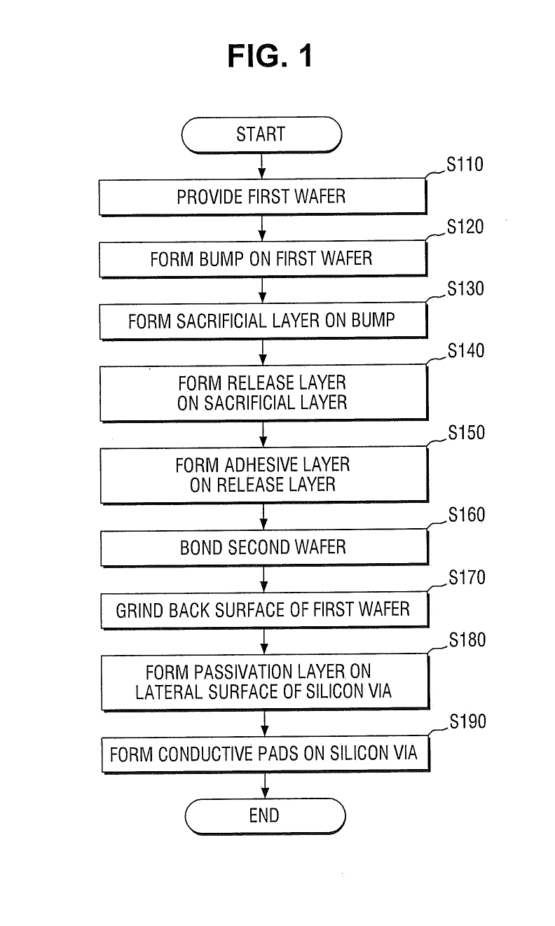

A fabricating method for a semiconductor device according to some embodiments of the present invention will be described with reference to FIGS. 1 to 10.

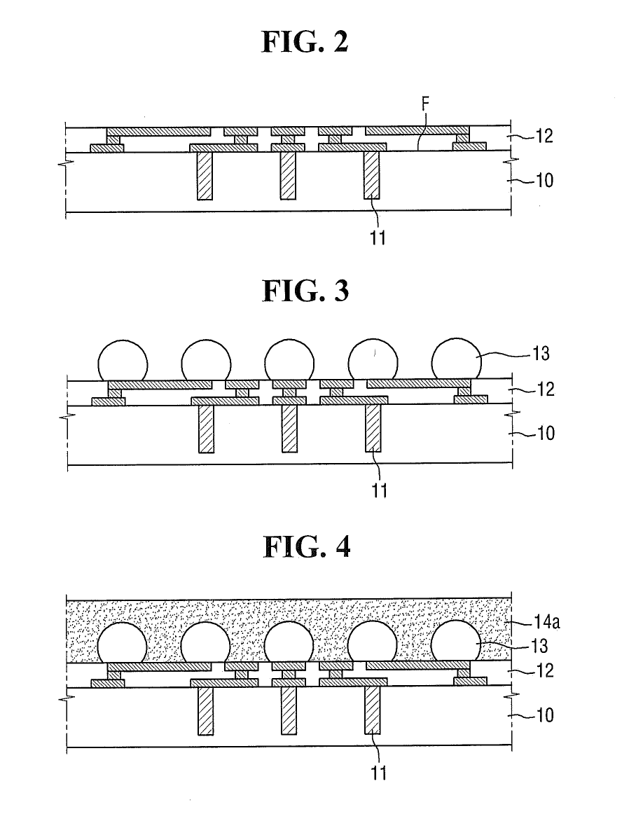

FIG. 1 is a schematic flowchart for explaining a fabricating method of a semiconductor device according to some embodiments of the present invention, and FIGS. 2 to 10 schematically illustrate a fabricating method of the semiconductor device according to some embodiments of the present invention.

Referring to FIG, 1, a first wafer 10 is provided (S110). The first wafer 10 may be, for example, a device wafer. The device wafer means a wafer having a semiconductor device, such as a transistor, formed thereon. Although not clearly shown, the first wafer 10 may include various structures, including a silicon layer, a silicon oxide layer, a high-k material layer, a metal layer, and so on.

Referring to FIG. 2, through silicon vias 11 are formed in the first wafer 10. The through silicon vias 11 may be filled with a conductive material. The through silicon vias 11 may be formed to a predetermined depth from a front surface F of the first wafer 10.

A wiring layer 12 is formed on the front surface F of the first wafer 10. The wiring layer 12 may include, for example, a redistributed layer (RDL), a back end of line (BEOL), and so on. The wiring layer 12 may include a plurality of metal wirings, and at least some of the metal wirings may be connected to the through silicon vias 11.

In the illustrated fabricating method of the semiconductor device according to some embodiments of the present invention, three through silicon vias 11 are formed in the first wafer 10, but aspects of the present invention are not limited thereto. One or more through silicon vias 11 may be formed in the first wafer 10.

Bumps 13 are formed on the front surface F of the first wafer 10 (S120). In more detail, the bumps 13 are formed on the wiring layer 12 of the first wafer 10.

Referring to FIG. 3, the bumps 13 are formed on the wiring layer 12. The bumps 13 may be made of, for example, Sn, Pb, Cu, or Au, but not limited thereto. The bumps 13 may be connected to at least some of the metal wires of the wiring layer 12.

A sacrificial layer 14a is formed on the bumps 13 (S130). The sacrificial layer 14a may be made of a material dissolved in an organic solvent, and may be formed by, for example, chemical vapor deposition (CVD), plasma enhanced chemical vapor deposition (PECVD), or spin on glass (SOG).

Referring to FIG. 4, the sacrificial layer 14a is formed to cover a top surface of the wiring layer 12 and the bumps 13. The sacrificial layer 14a may be made of silicon oxide, such as SiO₂. The sacrificial layer 14a may be formed by, for example, spin coating, but aspects of the present invention are not limited thereto. The sacrificial layer 14a may be formed by various known coating methods. The sacrificial layer 14a may be formed to have various thicknesses in consideration of characteristics of the device wafer.

A release layer 15a is formed on the sacrificial layer 14a (S140). An adhesive layer 16 is formed on the release layer 15a (S150).

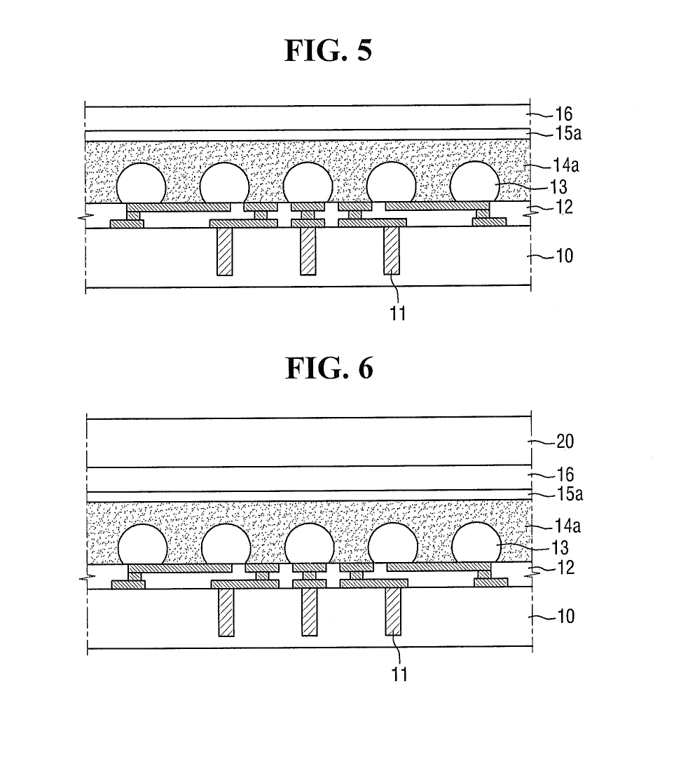

Referring to FIG. 5, the release layer 15a is formed on the sacrificial layer 14a. The release layer 15a may be formed by coating an organic compound, such as polyimide, on a metal layer made of, for example, Cu or Al, but aspects of the present invention are not limited thereto. The release layer 15a is dissolved or detached in a step of removing the second wafer 20, which will later be described, and may function to remove the second wafer 20 from the first wafer 10.

The adhesive layer 16 is formed on the release layer 15a. The adhesive layer 16 may be formed by, for example, coating at least one adhesive material selected from the group consisting of polymer, oligomer, and monomer, on the release layer 15a, and baking the coated adhesive material layer, but embodiments of the present invention are not limited thereto.

An organic material reacting or not reacting with ultra violet (UV) may be used to form the release layer 15a or the adhesive layer 16. The release layer 15a or the adhesive layer 16 may be formed of a polyethylene terephthalate (PET) film coated with poly-acryl based polymer.

The first wafer 10 and the second wafer 20 are bonded to each other (S160). The second wafer 20 may be, for example, a carrier wafer. A carrier wafer may be a wafer without a semiconductor device formed thereon. The second wafer 20 may be bonded to the first wafer 10 in a step of back-grinding the first wafer 10, which will later be described, and may support the first wafer 10.

Referring to FIG. 6, the second wafer 20 is placed on the adhesive layer 16, and the first wafer 10 and the second wafer 20 are bonded to each other. The second wafer 20 may be made of, for example, glass or silicon, but embodiments of the present invention are not limited thereto. The second wafer 20 may have the same size as the first wafer 10.

A back surface B of the first wafer 10 may be ground (S170).

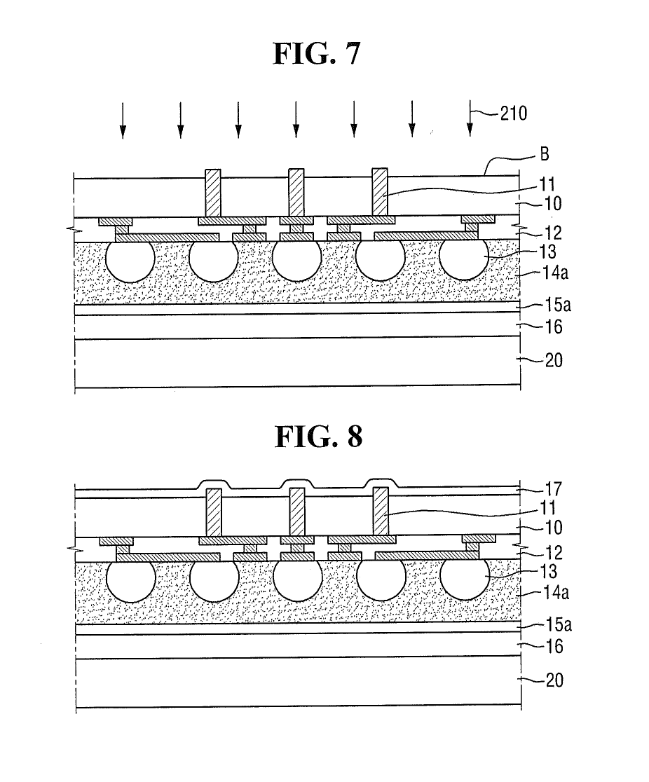

Referring to FIG. 7, the first wafer 10 may be formed to have a predetermined thickness by grinding the back surface B of the first wafer 10. The ground first wafer 10 may have a thickness of, for example, several micrometers (μm). The first wafer 10 may be ground using, for example, a through-feed method or an in-feed method, but embodiments of the present invention are not limited thereto. The first wafer 10 may be ground using various known grinding methods.

After grinding the back surface B of the first wafer 10, top surfaces of the through silicon vias 11 are exposed to the outside of the first wafer 10.

A passivation layer 17 is formed on lateral surfaces of the through silicon vias 11 (S180). The passivation layer 17 may protect the first wafer 10 from external circumstances, such as heat or humidity, and mechanical stress.

Referring to FIG. 8, the passivation layer 17 is formed along the top surfaces and lateral surfaces of the exposed through silicon vias 11 on the back surface B of the first wafer 10. The passivation layer 17 may be made of, for example, polyimide, but not limited thereto.

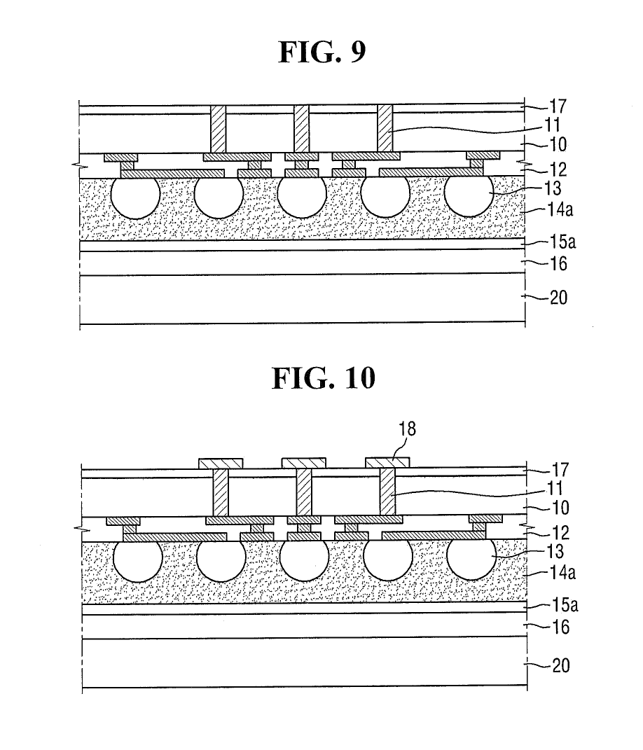

Referring to FIG. 9, the passivation layer 17 is planarized by etching the same to heights of the top surfaces of the through silicon vias 11 so as to expose the top surfaces of the through silicon vias 11.

Conductive pads 18 are formed on the through silicon vias 11 (S190). The conductive pads 18 may be connected to the micro bumps 31 of the semiconductor chips 30 in a step of stacking the semiconductor chips 30, which will be described later.

Referring to FIG. 10, the conductive pads 18 are formed on the through silicon vias 11. The conductive pads 18 may be made of, for example, Al, but not limited thereto.

In the fabricating method of the semiconductor device according to some embodiments of the present invention, since the sacrificial layer 14a covering the bumps 13 is formed, and the release layer 15a is formed on the sacrificial layer 14a, uniform bonding energy or debonding energy may be exhibited, irrespective of the bump density in steps of bonding the first wafer and the second wafer to each other and removing the second wafer, which will later be described. Therefore, the debonding yield can be uniformly improved, irrespective of the bump density.

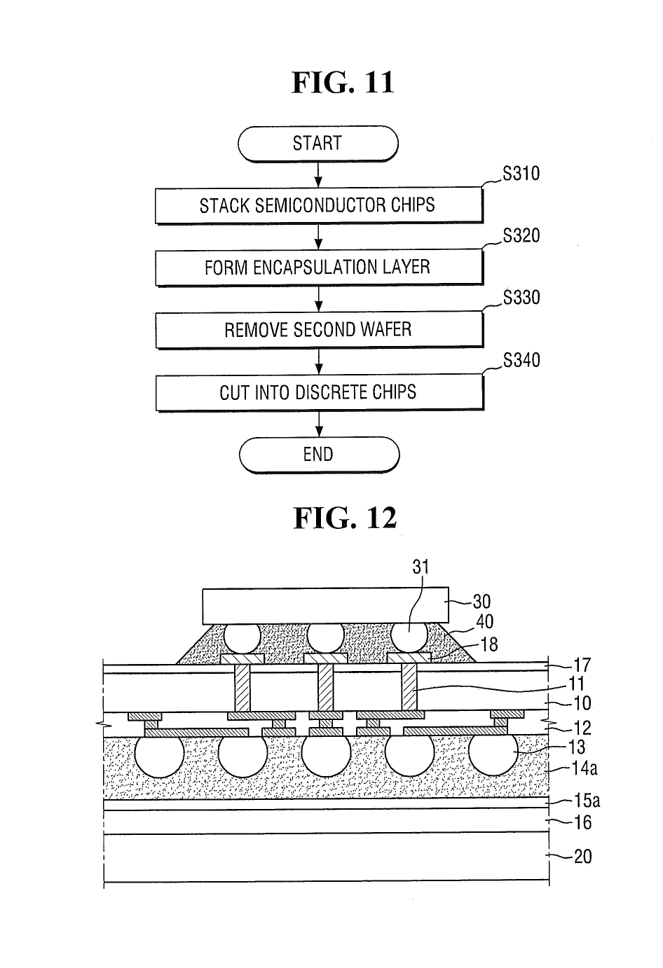

FIG. 11 is a schematic flowchart for explaining a fabricating method of a semiconductor package using a fabricating method of a semiconductor device according to some embodiments of the present invention, and FIGS. 12 to 14 schematically illustrate a fabricating method of the semiconductor package using a fabricating method of a semiconductor device according to some embodiments of the present invention.

For purposes of explanation, the fabricating method of the semiconductor package using the fabricating method of the semiconductor device according to some embodiments of the present invention will be described with reference to FIGS. 12 to 14. Embodiments of the present invention may also be applied to fabricating methods of the semiconductor devices according to other embodiments of the present invention.

Referring to FIG. 11, semiconductor chips 30 are stacked on the exposed through silicon vias 11 of the first wafer 10 (S310). The semiconductor chips 30 may be, for example, memory chips. In this case, the first wafer 10 may be a controller wafer for controlling the memory chips,

Referring to FIG. 12, the semiconductor chips 30 are stacked on the through silicon vias 11. In more detail, micro bumps 31 of the semiconductor chips 30 are connected to the conductive pads 18, and the semiconductor chips 30 are electrically connected to the through silicon vias 11 through the conductive pads 18.

An underfill layer 40 may be formed in an empty space between the semiconductor chips 30 and the first wafer 10. The underfill layer 40 may be made of, for example, epoxy, but not limited thereto. The underfill layer 40 may fix the semiconductor chips 30 on the first wafer 10 and may protect the conductive pads 18 of the first wafer 10 and the bumps 31 of the semiconductor chips 30 from external circumstances.

An encapsulation layer 50 is formed (S320). The encapsulation layer 50 may protect the semiconductor chips 30 from external circumstances.

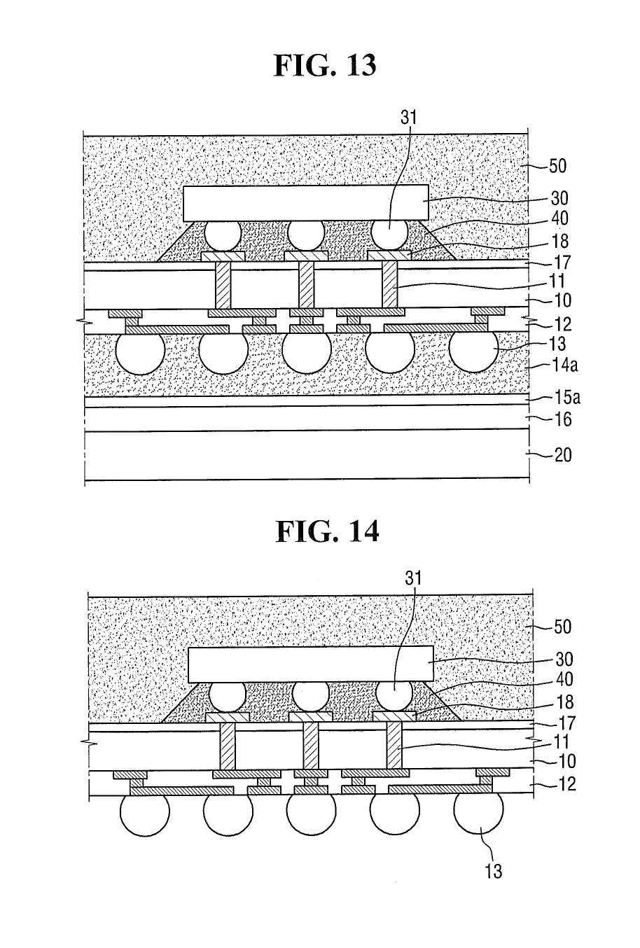

Referring to FIG. 13, the encapsulation layer 50 is formed on the semiconductor chips 30 to entirely surround the semiconductor chips 30. The encapsulation layer 50 may include, for example, epoxy mold compound (EMC) or resin, but not limited thereto.

The second wafer 20 bonded to the first wafer 10 is removed (S330). The second wafer 20 may be debonded from the first wafer 10 by etching the sacrificial layer 14a. To this end, the sacrificial layer 14a may have high etching selectivity with respect to the wiring layer 12 and the bumps 13. The second wafer 20 may be removed using plasma etching, but not limited thereto. The second wafer 20 may be removed using various dry or wet etching techniques.

A release layer 15a is released to debond the second wafer 20 from the first wafer 10, and the sacrificial layer 14a remaining on the first wafer 10 may then be etched. In this case, the debonding may be performed in various methods. For example, a chemical solvent for dissolving the release layer 15a may be used, the release layer 15a may be exposed to light for photolysis, the release layer 15a may be heated at a temperature or higher for dissociating the release layer 15a, or the release layer 15a may be softened for mechanical debonding, but embodiments of the present invention are not limited thereto.

When the release layer 15a or an adhesive layer 16 is formed of a polyethylene terephthalate (PET) film coated with poly-acryl based polymer, it can be released by irradiating ultra violet (UV). When the UV is irradiated, nitrogen (N₂) is outgassed from the release layer 15a or the adhesive layer 16 and the second wafer 20 is bonded from the first wafer 10. The remaining release layer 15a or the remaining adhesive layer 16 may be removed after debonding the second wafer 20.

Referring to FIG. 14, as the result of removing the second wafer 20, the bumps 13 of the first wafer 10 and the wiring layer 12 are exposed. The bumps 13 of the first wafer 10 may be connected to wirings of a package substrate in a subsequent packaging step.

The first wafer 10 having the semiconductor chips 30 stacked thereon are cut into discrete chips (S340).

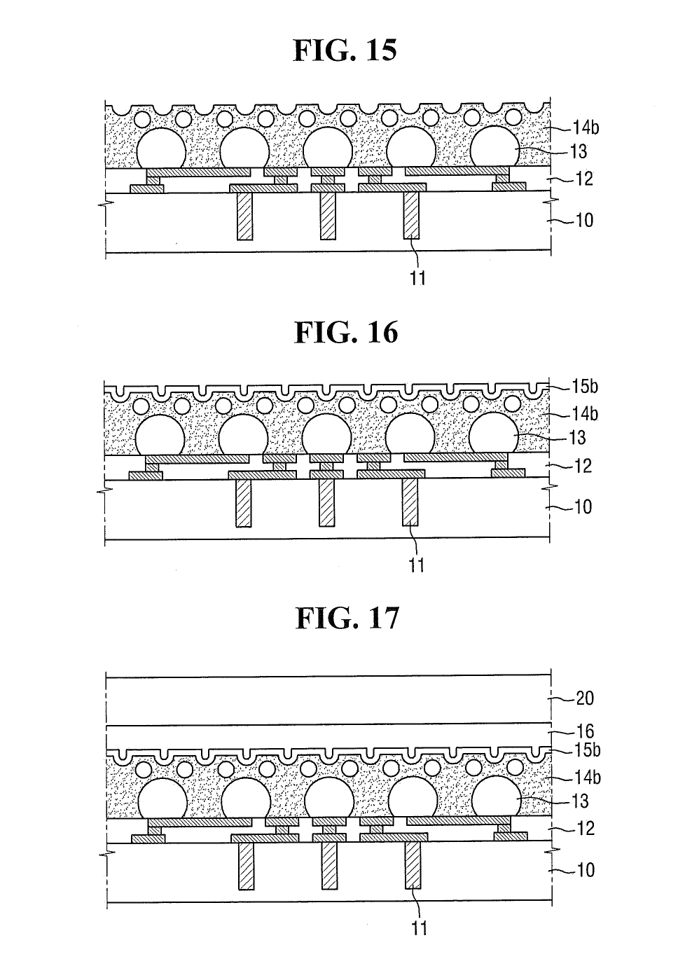

FIGS. 15 to 17 schematically illustrate a fabricating method of a semiconductor device according to some embodiments of the present invention. For the sake of convenient explanation, the following description will focus on differences between the present embodiments and the previous embodiments shown in FIGS. 4 to 6.

Referring to FIG. 15, a sacrificial layer 14b is formed to cover a top surface of the wiring layer 12 and the bumps 13. Here, the sacrificial layer 14b may be a porous sacrificial layer having porosity. The porous sacrificial layer 14b may have porosity of, for example, approximately less than 90%, but not limited thereto. The porosity of the porous sacrificial layer 14b may be adjusted according to desired bonding energy or debonding energy.

The porous sacrificial layer 14b may be made of, for example, silicon oxide, such as SiO₂. The porous sacrificial layer 14b may be made of a material dissolved in an organic solvent. The porous sacrificial layer 14b may be formed by, for example, spin coating, but embodiments of the present invention are not limited thereto. The porous sacrificial layer 14b may be formed by various known coating methods. The porous sacrificial layer 14b may be formed to have various thicknesses in consideration of characteristics of the device wafer.

Referring to FIG. 16, a release layer 15b is formed on the porous sacrificial layer 14b. Since the release layer 15b is conformally on the porous sacrificial layer 14b, as shown in FIG. 16, a surface area of the release layer 15b may be increased.

The release layer 15b may be formed by coating an organic compound, such as polyimide, on a metal layer made of, for example, Cu or Al, but aspects of the present invention are not limited thereto.

The adhesive layer 16 is formed on the release layer 15b. The adhesive layer 16 may be formed by, for example, coating at least one adhesive material selected from the group consisting of polymer, oligomer, and monomer, on the release layer 15b, and baking the coated adhesive material layer, but embodiments of the present invention are not limited thereto.

An organic material reacting or not reacting with ultra violet (UV) may be used to form the release layer 15b or the adhesive layer 16. The release layer 15b or the adhesive layer 16 may be formed of a polyethylene terephthalate (PET) film coated with poly-acryl based polymer.

Referring to FIG. 17, the second wafer 20 is disposed on the adhesive layer 16 and bonded to the first wafer 10. The second wafer 20 may be made of, for example, glass or silicon, but embodiments of the present invention are not limited thereto. The second wafer 20 may have the same size as the first wafer 10.

In a fabricating method of the semiconductor device according to some embodiments of the present invention, the porous sacrificial layer 14b is formed, so that the surface area of the release layer 15b is increased, thereby increasing bonding energy in bonding the first wafer 10 and the second wafer 20 to each other. In addition, the porous sacrificial layer 14b has an increased an etch rate, compared to the common sacrificial layer 14a, thereby easily debonding the second wafer 20 from the first wafer 10 in removing the second wafer 20 from the first wafer 10.

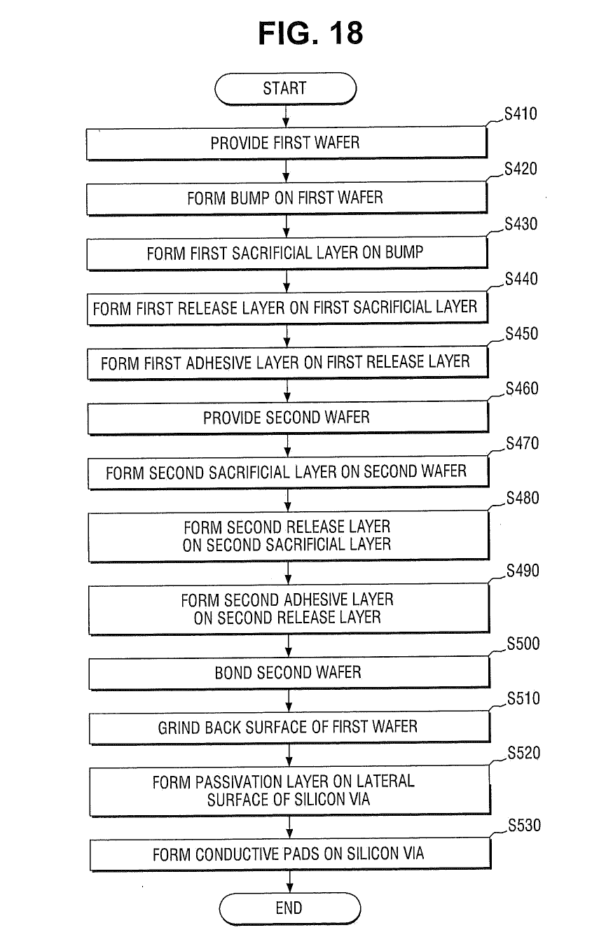

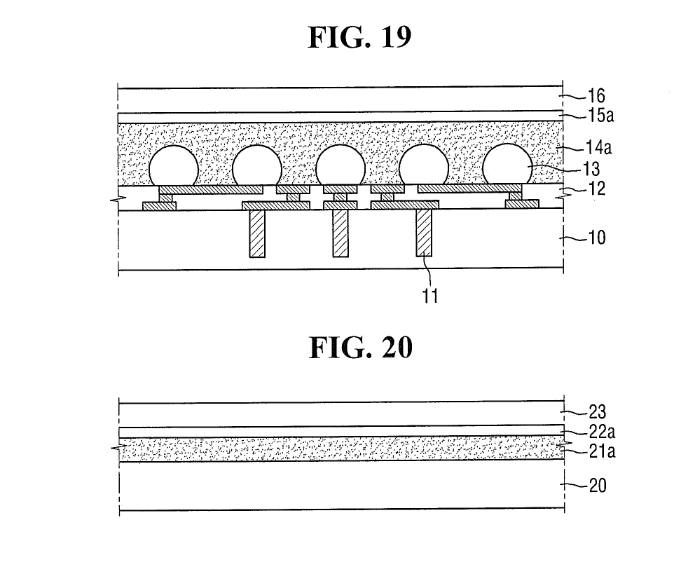

FIG. 18 is a schematic flowchart for explaining a fabricating method of a semiconductor device according to some embodiments of the present invention, and FIGS. 19 to 21 schematically illustrate a fabricating method of the semiconductor device according to some embodiments of the present invention. For the sake of convenient explanation, the following description will focus on differences between the present embodiments and the previous embodiments shown in FIG. 1.

Referring to FIG. 18, a first wafer 10 is provided (S410). The first wafer 10 may be, for example, a device wafer. As described above, the first wafer 10 may include various structures, including a silicon layer, a silicon oxide layer, a high-k material layer, a metal layer, and so on.

Bumps 13 are formed on a front surface F of the first wafer 10 (S420). In more detail, the bumps 13 are formed on a wiring layer 12 of the first wafer 10. A first sacrificial layer 14a is formed on the bumps 13 (S430). A first release layer 15a is formed on the first sacrificial layer 14a (S440). A first adhesive layer 16 is formed on the first release layer 15a (S450).

The blocks S410 to S450 are substantially the same as the blocks S110 to S150 described with reference to FIG. 1, and a detailed description thereof will be omitted.

Referring to FIG. 19, a second wafer 20 is not directly disposed on the first adhesive layer 16, but temporarily exposes the first adhesive layer 16.

The second wafer 20 is provided (S460). The second wafer 20 may be, for example, a carrier wafer. The carrier wafer may be a wafer without a semiconductor device formed thereon.

A second sacrificial layer 21a is formed on the second wafer 20 (S470). The second sacrificial layer 21a may be made of a material dissolved in an organic solvent, and may be formed by, for example, chemical vapor deposition (CVD), plasma enhanced chemical vapor deposition (PECVD), or spin on glass (SOG).

Referring to FIG. 20, the second sacrificial layer 21a may be formed on the second wafer 20. The second sacrificial layer 21a may be made of silicon oxide, such as SiO₂. The second sacrificial layer 21a may be made of a material dissolved in an organic solvent. The second sacrificial layer 21a may be formed by, for example, spin coating, but embodiments of the present invention are not limited thereto. The second sacrificial layer 21a may be formed by various known coating methods. The second sacrificial layer 21a may be formed to have various thicknesses in consideration of characteristics of the device wafer.

A second release layer 22a is formed on the second sacrificial layer 21a (S480). A second adhesive layer 23 is formed on the second release layer 22a (S490).

Referring again to FIG. 20, the second release layer 22a is formed on the second sacrificial layer 21a. The second release layer 22a may be formed by coating an organic compound, such as polyimide, on a metal layer made of, for example, Cu or Al, but aspects of the present invention are not limited thereto.

The second adhesive layer 23 is formed on the second release layer 22a. The second adhesive layer 23 may be formed by, for example, coating at least one adhesive material selected from the group consisting of polymer, oligomer, and monomer, on the second release layer 22a, and baking the coated adhesive material layer, but embodiments of the present invention are not limited thereto.

An organic material reacting or not reacting with ultra violet (UV) may be used to form the second release layer 22a or the second adhesive layer 23. The second release layer 22a or the second adhesive layer 23 may be formed of a polyethylene terephthalate (PET) film coated with poly-acryl based polymer.

The first wafer 10 and the second wafer 20 are bonded to each other (S500). The second wafer 20 is bonded to the first wafer 10 and supports the first wafer 10 in the step of back-grinding the first wafer 10.

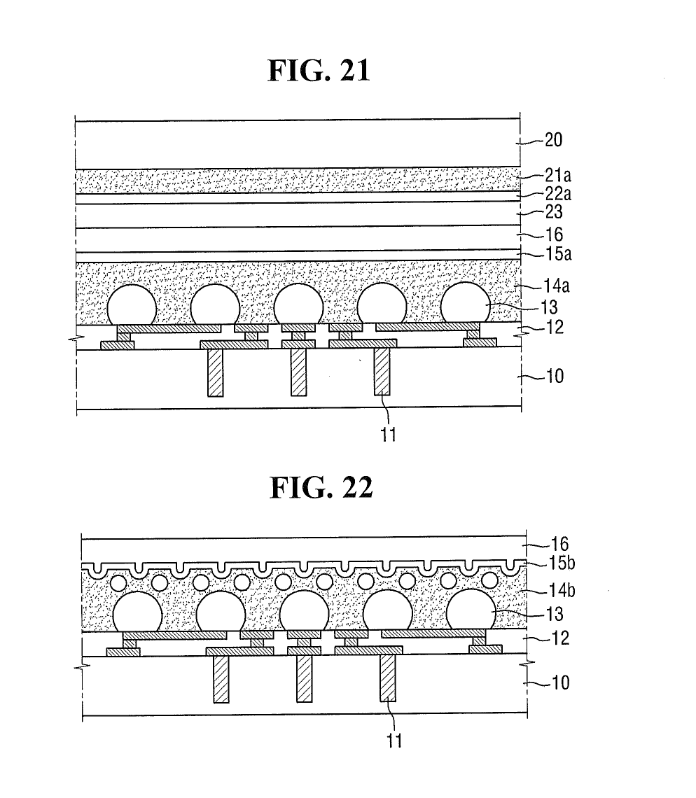

Referring to FIG. 21, the second adhesive layer 23 is disposed on the first adhesive layer 16, and the first wafer 10 and the second wafer 20 are bonded to each other. The second wafer 20 may be made of, for example, glass or silicon, but embodiments of the present invention are not limited thereto. The second wafer 20 may have the same size as the first wafer 10.

The blocks S510 to S530 are substantially the same as the blocks S160 to S190 described with reference to FIG. 1, and a detailed description thereof will be omitted.

In the fabricating method of a semiconductor package using the fabricating method of the semiconductor device according to some embodiments of the present invention, when the second wafer 20 bonded to the first wafer 10 is removed, the second wafer 20 may be debonded from the first wafer 10 by etching the second sacrificial layer 21a as well as first sacrificial layer 14a.

FIGS. 22 to 24 schematically illustrate a fabricating method of a semiconductor device according to some embodiments of the present invention. For the sake of convenient explanation, the following description will focus on differences between the present embodiment and the previous embodiment shown in FIGS. 19 to 21.

Referring to FIG. 22, the first sacrificial layer 14b is formed to cover a top surface of the wiring layer 12 and the bumps 13. Here, the first sacrificial layer 14b may be a porous sacrificial layer having porosity. The first release layer 15a is formed on the first porous sacrificial layer 14b. The first adhesive layer 16 is formed on the first release layer 15a.

The forming of the first sacrificial layer 14a, the first release layer 15a, and the first adhesive layer 16 are substantially the same as described above with reference to FIGS. 15 to 17, and a detailed description thereof will be omitted.

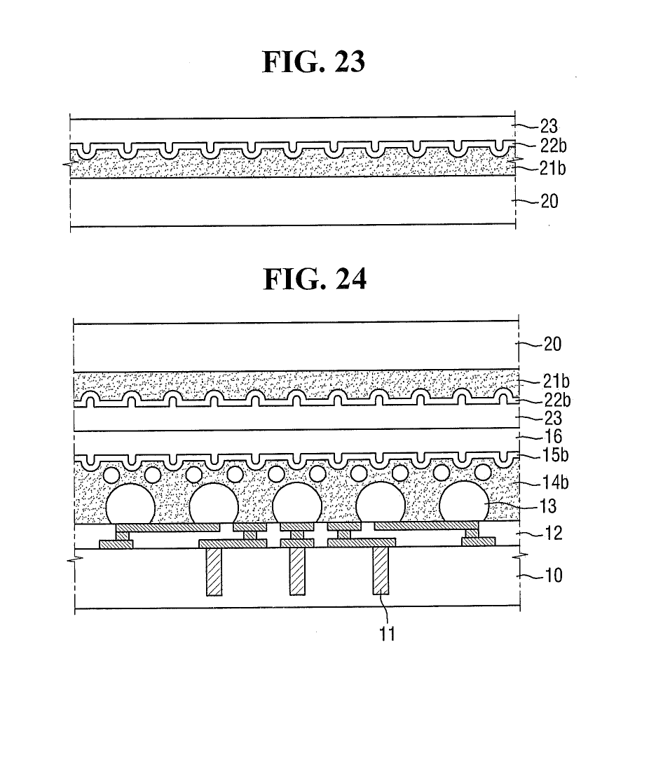

Referring to FIG. 23, the second sacrificial layer 21b is formed on the second wafer 20. Here, the second porous sacrificial layer 21b may be a porous sacrificial layer having porosity. The second porous sacrificial layer 21b may have porosity of, for example, approximately less than 90%, but not limited thereto. The porosity of the second sacrificial layer 21b may be adjusted according to desired bonding energy or debonding energy.

The second porous sacrificial layer 21b may be made of, for example, silicon oxide, such as SiO₂. The second porous sacrificial layer 21b may be made of a material dissolved in an organic solvent. The second porous sacrificial layer 21b may be formed by, for example, spin coating, but aspects of the present invention are not limited thereto. The second porous sacrificial layer 21b may be formed by various known coating methods. The second porous sacrificial layer 21b may be formed to have various thicknesses in consideration of characteristics of the device wafer.

A second release layer 22b is formed on the second porous sacrificial layer 21b. The second release layer 22b may be formed by coating an organic compound, such as polyimide, on a metal layer made of, for example, Cu or Al, but aspects of the present invention are not limited thereto.

The second adhesive layer 23 is formed on the second release layer 22b. The second adhesive layer 23 may be formed by, for example, coating at least one adhesive material selected from the group consisting of polymer, oligomer, and monomer, on the second release layer 22b, and baking the coated adhesive material layer, but aspects of the present invention are not limited thereto.

An organic material reacting or not reacting with ultra violet (UV) may be used to form the second release layer 22b or the second adhesive layer 23. The second release layer 22b or the second adhesive layer 23 may be formed of a polyethylene terephthalate (PET) film coated with poly-acryl based polymer.

Referring to FIG. 24, the second adhesive layer 23 is disposed on the first adhesive layer 16, and the first wafer 10 and the second wafer 20 are bonded to each other. The second wafer 20 may be made of, for example, glass or silicon, but embodiments of the present invention are not limited thereto. The second wafer 20 may have the same size as the first wafer 10.

Although not clearly shown, base film may be interposed between the first wafer 10 and the second wafer 20. The base film may have a thickness of, for example, 50 μm. The base film may be made of, for example, PET, but embodiments of the present invention are not limited thereto.

The first adhesive layer 16 that adheres the first wafer 10 to the base film may be formed as a UV releasing adhesive layer, and the second adhesive layer 23 that adheres the second wafer 20 to the base film may be formed as an UV self-releasing adhesive layer. The first adhesive layer 16 may have a thickness of, for example, 20 μm, and the second adhesive layer 23 may have a thickness in a range of, for example, approximately 50 to 110 μm, but embodiments of the present invention are not limited thereto.

In order to remove the second wafer 20, the second wafer 20 may be released from the base film by irradiating UV. When the UV is irradiated, nitrogen (N₂) is outgassed from the second adhesive layer 23 and the second wafer 20 is bonded from the base film. The remaining second adhesive layer 23, the base film and the first adhesive layer 16 may be removed after debonding the second wafer 20.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A fabricating method for a semiconductor device comprising:
providing a first wafer;
forming bumps on the first wafer;
forming a sacrificial layer on the bumps of the first wafer;
forming a release layer on the sacrificial layer;
forming an adhesive layer on the release layer; and
placing a second wafer on the adhesive layer and bonding the first wafer to the second wafer.

2. The fabricating method of claim 1, wherein the forming of the sacrificial layer comprises forming the sacrificial layer including silicon oxide.

3. The fabricating method of claim 1, wherein the forming of the sacrificial layer comprises forming the sacrificial layer including a porous layer.

4. A fabricating method for a semiconductor device comprising:
providing a first wafer having one or more through silicon vias formed therein;
forming a first sacrificial layer on the first wafer;
forming a first release layer on the first sacrificial layer;
forming a first adhesive layer on the first release layer;
placing a second wafer on the first adhesive layer and bonding the first wafer to the second wafer; and
back-grinding the first wafer to expose the one or more through silicon vias.

5. The fabricating method of claim 4, wherein the forming of the first sacrificial layer comprises forming the first sacrificial layer including silicon oxide.

6. The fabricating method of claim 4, wherein the forming of the first sacrificial layer comprises forming the first sacrificial layer including a porous layer.

7. The fabricating method of claim 4, wherein the forming of the first sacrificial layer on the first wafer comprises forming bumps on the first wafer and forming the first sacrificial layer on the bump.

8. The fabricating method of claim 4, further comprising stacking semiconductor chips on the exposed one or more through silicon vias.

9. The fabricating method of claim 8, further comprising removing the second wafer bonded to the first wafer by etching the first sacrificial layer.

10. The fabricating method of claim 4, further comprising:
forming a second sacrificial layer on the second wafer;
forming a second release layer on the second sacrificial layer; and
forming a second adhesive layer on the second release layer,
wherein the bonding of the first wafer with the second wafer comprises placing the second adhesive layer on the first adhesive layer and bonding the first wafer with the second wafer.

11. The fabricating method of claim 10, wherein the forming of the second sacrificial layer comprises forming the second sacrificial layer including silicon oxide.

12. The fabricating method of claim 10, wherein the forming of the second sacrificial layer comprises forming the second sacrificial layer including a porous layer.

13. The fabricating method of claim 10, further comprising stacking semiconductor chips on the exposed one or more through silicon vias.

14. The fabricating method of claim 13, further comprising removing the second wafer bonded to the first wafer by etching the first sacrificial layer and the second sacrificial layer.

15. A method of forming a semiconductor device comprising:
providing a first wafer;
forming a porous sacrificial layer on the first wafer;
forming a release layer on the porous sacrificial layer;
forming an adhesive layer on the release layer; and
placing a second wafer on the adhesive layer and bonding the first wafer to the second wafer,

16. The method of claim 15, wherein forming the porous sacrificial layer comprises forming the porous sacrificial layer with less than 90% porosity.

17. The method of claim 15, wherein the porous sacrificial layer comprises a first porous sacrificial layer, the method further comprising:
forming a second porous sacrificial layer on the second wafer;
forming a second release layer on the second porous sacrificial layer; and
forming a second adhesive layer on the second release layer,
wherein bonding the first wafer to the second wafer comprises placing the second adhesive layer on the first adhesive layer.

18. The method of claim 15, wherein forming the release layer comprises:
forming a metal layer; and
forming an organic compound layer on the metal layer.

19. The method of claim 18, wherein forming the organic compound layer comprises forming an organic compound that reacts with ultra violet light to release the second wafer from the first wafer.

20. The method of claim 15, further comprising forming a base film between the first and second wafers.
